(19) United States
(12) Patent Application Publication
(10) Pub. No.: US 2018/0277232 A1
(43) Pub. Date: Sep. 27, 2018

(54) SHIFT REGISTER

(71) Applicant: INT TECH CO., LTD., Taipei (TW)

(72) Inventor: Shih-Song CHENG, Kaohsiung (TW)

(21) Appl. No.: 15/470,200

(22) Filed: Mar. 27, 2017

(51) Int. Cl. G11C 19/28

(52) U.S. Cl. CPC G11C 19/28

(57) ABSTRACT

A shift register including a number of register stages is disclosed. Each of the register stages includes a first transistor that includes a gate to receive a first control signal (XCK), and a source to receive an input signal in response to the first control signal, a second transistor that includes a source to receive a supply voltage, and a third transistor that includes a gate coupled to the drain of the first transistor, a source to receive a second control signal, and a drain to provide the input signal as an output in response to the second control signal.

### BACKGROUND

Shift registers are a form of sequential logic. Sequential logic, unlike combinational logic, is not only affected by the present input and rather is affected by a prior input. In other words, sequential logic remembers past events. Shift registers produce a discrete delay of a digital signal or waveform. A waveform synchronized to a clock, a repeating square wave, is delayed by “n” discrete clock times in a shift register with n-stages long. The stages in a shift register are delay stages, typically type “D” Flip-Flops or type “JK” Flip-flops. Numerous peripherals, including analog to digital converters, digital to analog converters, display drivers, and memory, use shift registers to reduce the amount of wiring in circuit boards.

### SUMMARY

Embodiments of the present invention provide a shift register that includes a number of register stages. Each of the register stages includes a first transistor that includes a gate to receive a first control signal (XCK), and a source to receive an input signal in response to the first control signal, a second transistor that includes a source to receive a supply voltage, and a third transistor that includes a gate coupled to the drain of the first transistor, a source to receive a second control signal, and a drain to provide the input signal as an output in response to the second control signal.

In an embodiment, the each register stage further includes a fourth transistor that includes a source to receive the supply voltage, and a drain coupled to the drain of the third transistor, a fifth transistor that includes a gate to receive a third control signal, a source to receive the supply voltage, and a drain coupled to the gate of the third transistor, and a sixth transistor that includes a gate to receive the third control signal, a source to receive the third control signal, and a drain coupled to a gate of the fourth transistor and to a drain of the second transistor.

In some embodiments, the shift register is composed of the first through sixth transistors.

In an embodiment, the drain of the first transistor is coupled to a gate of the second transistor. Moreover, the each register stage further includes a capacitor coupled between the source and the drain of the second transistor.

In another embodiment, the source of the first transistor is coupled to a gate of the second transistor. Moreover, the each register stage further includes a capacitor coupled between the source and the drain of the second transistor.

In yet another embodiment, each of the first through sixth transistors includes a p-type transistor, and the supply voltage has a logically high level.

In still another embodiment, each of the first through sixth transistors includes an n-type transistor, and the supply voltage has a logically low level.

In yet still another embodiment, the first transistor is configured to receive an initial signal as the input signal.

In another embodiment, the first transistor is configured to receive an output from a previous register stage as the input signal.

In yet another embodiment, the input signal has a period of one frame time, and a pulse width not greater than one line time.

In still another embodiment, the first control signal has a period of two line times, and a pulse width not greater than one line time.

In yet still another embodiment, the second control signal has a period of two line times, and a pulse width not greater than one line time.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a shift register, in accordance with some embodiments.

FIG. 2A is a circuit diagram of an exemplary register stage in the shift register illustrated in FIG. 1, in accordance with an embodiment.

FIG. 2B is a timing diagram of signals for operation of the exemplary register stage illustrated in FIG. 2A, in accordance with some embodiments.

FIGS. 3A and 3B are diagrams showing circuit operation of the exemplary register stage illustrated in FIG. 2A during a first phase, in accordance with some embodiments.

FIGS. 4A and 4B are diagrams showing circuit operation of the exemplary register stage illustrated in FIG. 2A during a second phase, in accordance with some embodiments.

FIGS. 5A and 5B are diagrams showing circuit operation of the exemplary register stage illustrated in FIG. 2A during a third phase, in accordance with some embodiments.

FIG. 6A is a circuit diagram of an exemplary register stage in the shift register illustrated in FIG. 1, in accordance with another embodiment.

FIG. 6B is a timing diagram of signals for operation of the exemplary register stage illustrated in FIG. 6A, in accordance with some embodiments.

FIG. 7A is a circuit diagram of an exemplary register stage in the shift register illustrated in FIG. 1, in accordance with yet another embodiment.

FIG. 7B is a circuit diagram of an exemplary register stage in the shift register illustrated in FIG. 1, in accordance with still another embodiment.

FIG. 7C is a circuit diagram of an exemplary register stage in the shift register illustrated in FIG. 1, in accordance with yet still another embodiment.

FIG. 8A is a circuit diagram of an exemplary register stage in the shift register illustrated in FIG. 1, in accordance with yet another embodiment.

FIG. 8B is a circuit diagram of an exemplary register stage in the shift register illustrated in FIG. 1, in accordance with still another embodiment.

FIG. 8C is a circuit diagram of an exemplary register stage in the shift register illustrated in FIG. 1, in accordance with yet still another embodiment.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it may be directly connected to or coupled to the other element, or intervening elements may be present.

In the below description, a signal is asserted with a logical high value to activate a corresponding device when the device is active high. In contrast, the signal is deasserted with a low logical value to deactivate the corresponding device. When the device is active low, however, the signal is asserted with a low logical value to activate the device, and is deasserted with a high logical value to deactivate the device.

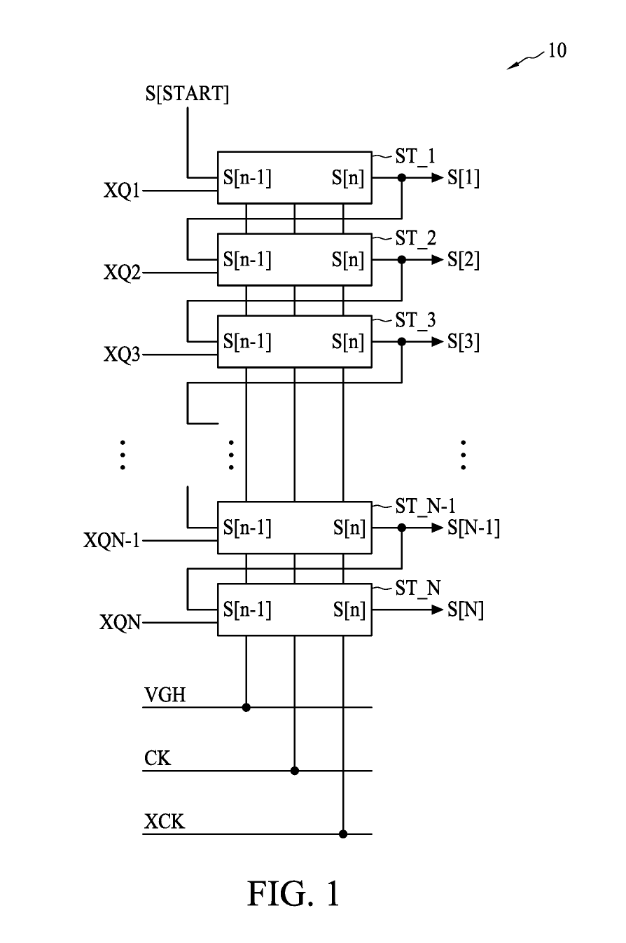

FIG. 1 is a block diagram of a shift register 10, in accordance with some embodiments.

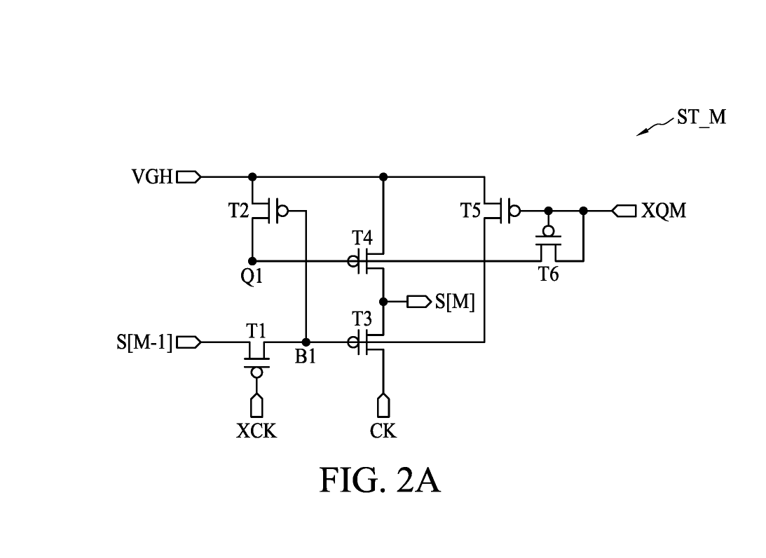

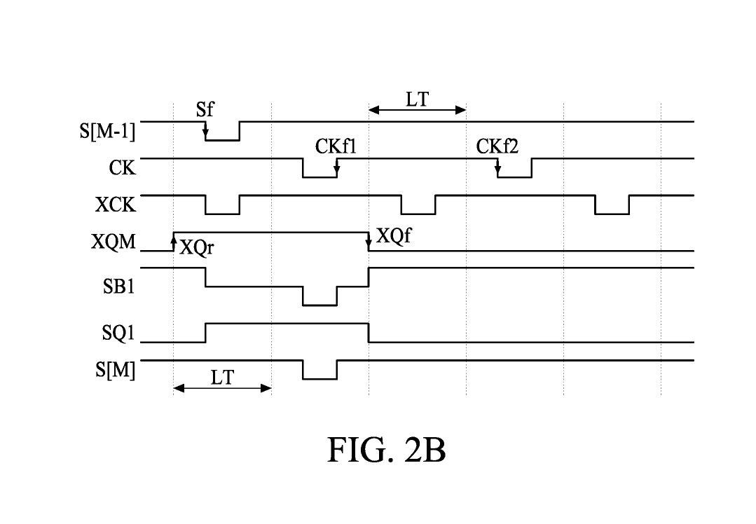

Referring to FIG. 1, the shift register 10 includes register stages ST_1 through ST_N, N being a natural number. Each of the register stages ST_1 through ST_N includes an input port S[n−1] for receiving an input from a previous register stage, and an output port S[n] for providing an output. Specifically, for example, a first register stage ST_1 receives an initial input S[START] at its input port S[n−1], and provides a first output S[1] at its output port S[N]. A second register stage ST_2 receives the first output S[1] at its input port S[n−1], and provides a second output S[2] at its output port S[N]. Likewise, an n-th register stage ST_N receives an (n−1)-th output S[N−1] at its input port S[n−1], and provides an n-th output S[N] at its output port S[N]. During operation of the shift register 10, each of the register stages ST_1 through ST_N receives control signals VGH, CK, XCK and a corresponding one of control signals XQ1 through XQN. These control signals VGH, CK, XCK and XQ1 through XQN will be discussed in detail with reference to FIG. 2B.

In the present embodiment, the shift register 10 with the N register stages ST_1 through ST_N is configured to serve as a serial-in-serial-out register. In other embodiments, however, by an appropriate arrangement of the register stages ST_1 through ST_N in conjunction with a commensurate timing sequence of the control signals VGH, CK, XCK and XQ1 through XQN, the shift register 10 may be configured to perform a serial-in-parallel-out, parallel-in-serial-out or parallel-in-parallel-out function, or to serve as a ring counter.

FIG. 2A is a circuit diagram of an exemplary register stage ST_M in the shift register 10 illustrated in FIG. 1, in accordance with an embodiment.

Referring to FIG. 2A, the register stage ST_M, M being a natural number from 1 to N, includes transistors T1 through T6. A gate of the transistor T1 receives the control signal XCK. A source of the transistor T1 receives an input signal S[M−1] from a previous register stage ST_M−1, if M is greater than 1, or an initial input S[START], if M equals 1. Further, a gate of the transistor T2 is coupled at a node B1 to a drain of the transistor T1. A source of the transistor T2 receives a supply voltage VGH, which may be 5 volts. In addition, a gate of the transistor T3 is coupled at the node B1 to the drain of the transistor T1 and also to the gate of the transistor T2. A source of the transistor T3 receives the control signal CK. A drain of the transistor T3 provides an output S[M].

Moreover, a gate of the transistor T4 is coupled at a node Q1 to a drain of the transistor T2. A source of the transistor T4 receives the supply voltage VGH. A drain of the transistor T4 is coupled to the drain of the transistor T3. Further, a gate of the transistor T5 receives the control signal XQM. A source of the transistor T5 receives the supply voltage VGH. A drain of the transistor T5 is coupled to the gate of the transistor T3 and also to the drain of the transistor T1 and the gate of the transistor T2. In addition, a gate of the transistor T6 receives the control signal XQM. A source of the transistor T6 also receives the control signal XQM. A drain of the transistor T6 is coupled to the gate of the transistor T4 and the drain of the transistor T2.

In the present embodiment, each of the transistors T1 through T6 includes a p-type thin film transistor (TFT) or a p-type metal-oxide-semiconductor (PMOS) transistor. Persons having ordinary skill in the art will understand that drain and source terminals of a MOS transistor may be interchangeable, depending on voltage levels applied thereto.

As far as circuit structure is concerned, the register stage ST_M is free from capacitor. Furthermore, the transistors T1 through T6 may serve as switches for controlling the operation of the register stage ST_M. As a result, the register stage ST_M has a relatively stable circuit operation. Additionally, the six-transistor (6T) structure of the register stage ST_M is relatively simple, which facilitates the shift register 10 to be fit for a narrow bezel design. Also, the shift register 10 may be applicable to a driving system in a low-temperature poly-silicon (LTPS), amorphous-silicon or oxide-TFT display.

FIG. 2B is a timing diagram of signals for operation of the exemplary register stage ST_M illustrated in FIG. 2A, in accordance with some embodiments.

Referring to FIG. 2B, the input signal S[M−1] has a period of one frame time, and a pulse width not greater than one (1) line time LT. In an embodiment, the frame time is approximately 16.7 milliseconds (ms), given sixty (60) frames per second. Accordingly, the line time LT is approximately 16.7/N ms. Also, the signals S[START] and S[M], since having a similar pulse pattern as the signal S[M−1], have a period of one frame time, and a pulse width not greater than 1 line time LT.

In the present embodiment, each of the control signals CK and XCK has a period of two (2) line times LT, and a pulse width not greater than 1 line time LT. Moreover, the control signal XCK leads (or lags) the control signal CK by one line time LT. As such, when the control signal CK is asserted, the control signal XCK is kept at a deasserted state, and when the control signal XCK is asserted, the control signal CK is kept at a deasserted state.

The control signal XQM has a period of one frame time. A rising edge XQr of the control signal XQM occurs prior to the falling edge Sf of the signal S[M−1] during the active line time of the signal S[M−1]. In addition, a falling edge XQf of the control signal XQM occurs posterior to a first falling edge CKf1 of the control signal CK during a first active line time of the control signal CK and prior to a second falling edge CKf2 of the control signal CK during a second active line time of the control signal CK. Additionally, signals detected at the nodes B1 and Q1 are denoted as SB1 and SQ1, respectively. In the present embodiment, the signals S[M−1], CK, XCK and XQM are configured to be active low in view of the p-type transistors T1 through T6.

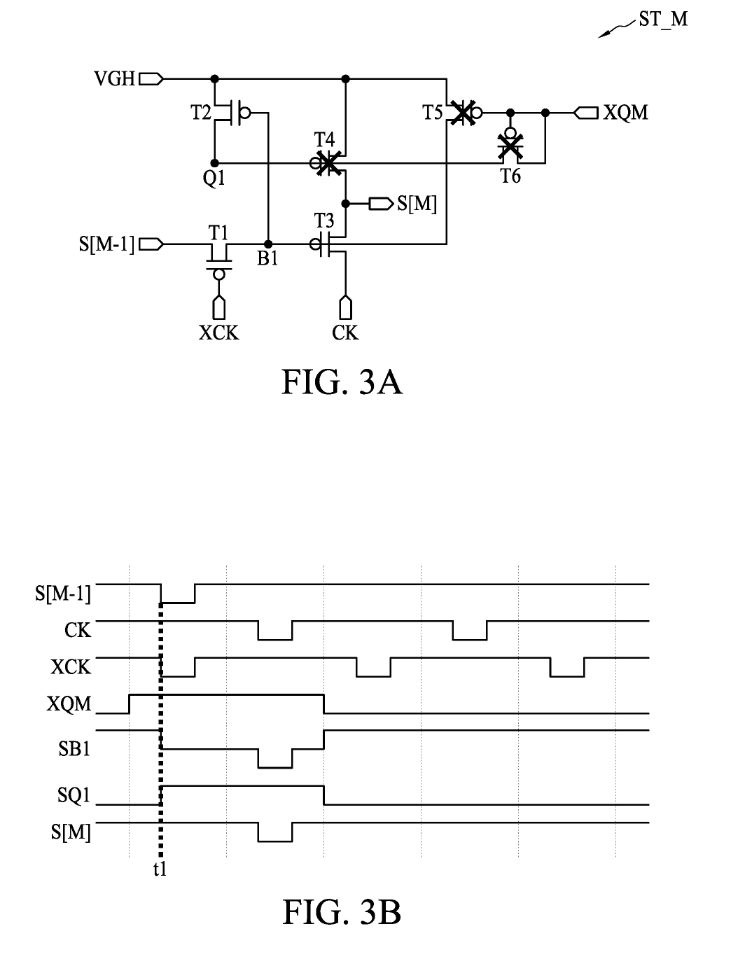

FIGS. 3A and 3B are diagrams showing circuit operation of the exemplary register stage ST_M illustrated in FIG. 2A during a first phase, in accordance with some embodiments.

Referring to FIG. 3B, at time t1, the control signal XCK is asserted, the control signals CK and XQM are kept at a deasserted state, and the input signal S[M−1] is logically low. Referring to FIG. 3A, in response to the logically low signal XCK, the transistor T1 is turned on. The logically low input signal S[M−1] at the source of the transistor T1 pulls low a voltage level at the node B1, which turns on the transistor T3. Meanwhile, the logically low signal SB1 at the node B1 also turns on the transistor T2. Accordingly, a voltage level at the node Q1 is pulled high to VGH, which turns off the transistor T4. In addition, since the control signal XQM is logically high, the transistors T5 and T6 are turned off. To facilitate reading, throughout the drawings, a transistor at an off state is labeled with a sign “X.”

As a result, at time t1, since the control signal CK is logically high and further since the transistor T3 is turned on, the output signal S[M] is logically high.

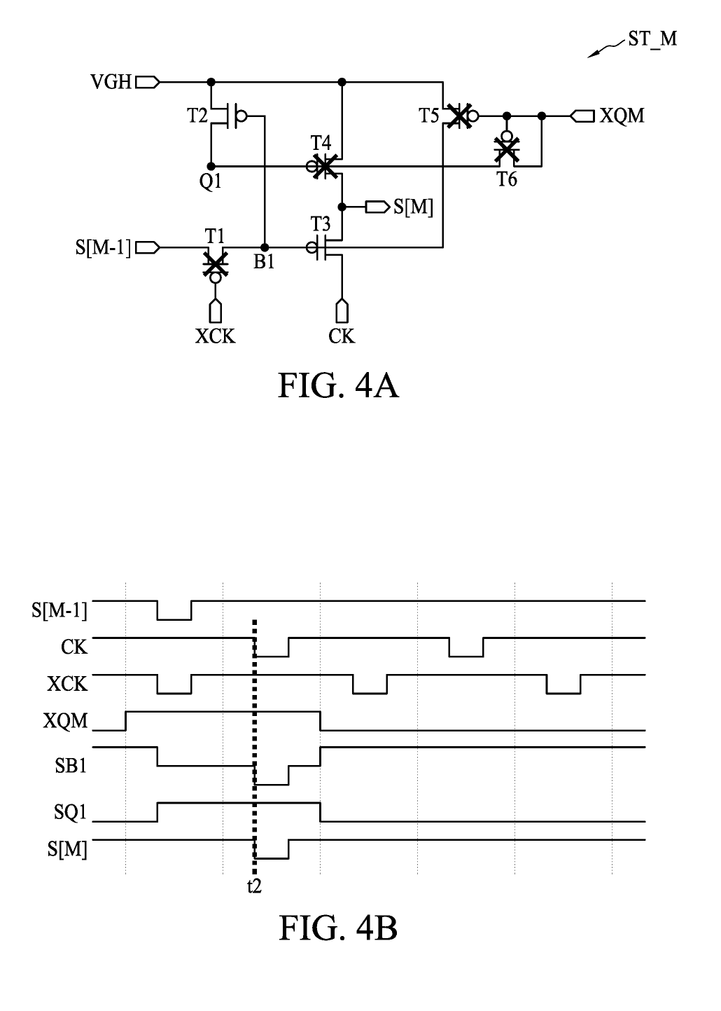

FIGS. 4A and 4B are diagrams showing circuit operation of the exemplary register stage ST_M illustrated in FIG. 2A during a second phase, in accordance with some embodiments.

Referring to FIG. 4B, at time t2, the control signal CK is asserted, and the control signals XCK and XQM are kept at a deasserted state. Referring to FIG. 4A, in response to the logically high signal XCK, the transistor T1 is turned off, which renders the node B1 floating. Due to channel capacitive coupling of the transistor T3, the signal SB1 at the node B1 is pulled lower than its previous state at time t1 by the logically low signal CK. The logically low signal SB1 keeps the transistors T2 and T3 at an on state. Meanwhile, the transistors T4, T5 and T6 are kept at an off state in view of the logically high signals SQ1 and XQM.

As a result, at time t2, since the control signal CK is logically low and further since the transistor T3 is turned on, the output signal S[M] becomes logically low.

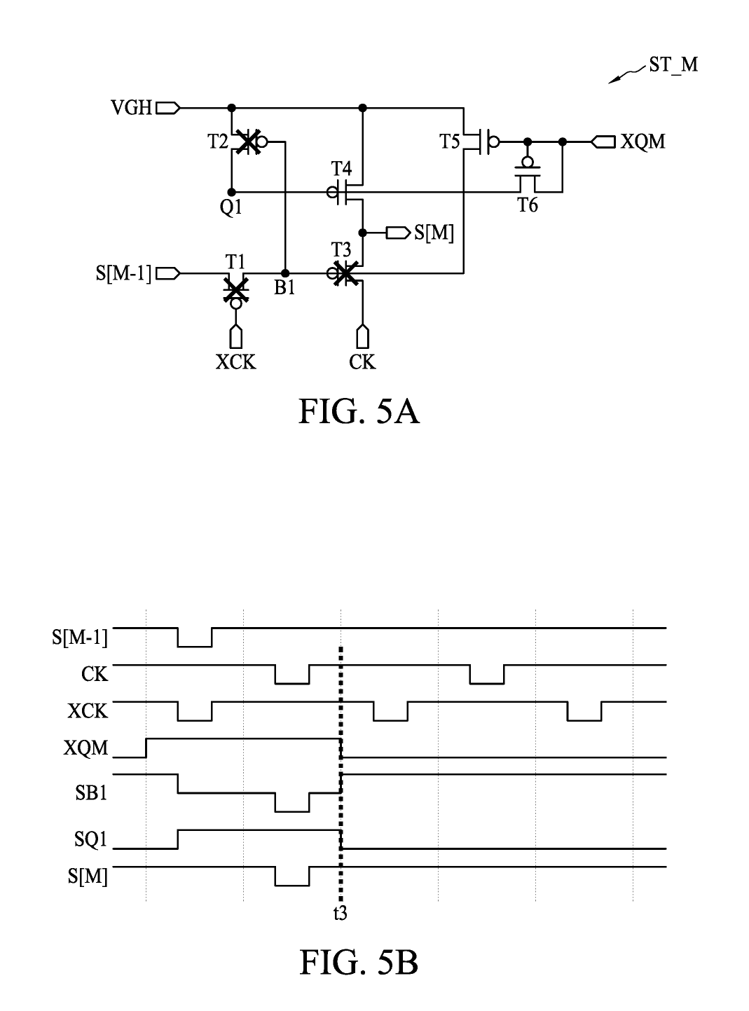

FIGS. 5A and 5B are diagrams showing circuit operation of the exemplary register stage ST_M illustrated in FIG. 2A during a third phase, in accordance with some embodiments.

Referring to FIG. 5B, at time t3, the control signal XQM is asserted, and the control signals CK and XCK are kept at a deasserted state. Referring to FIG. 5A, since the control signal XCK is logically high, the transistor T1 is kept at an off state. The signal SB1, due to channel capacitive coupling of the transistor T3, is pulled to a high logic level by the logically high signal CK. The logically high signal SB1 turns off the transistors T2 and T3. Meanwhile, the transistors T4, T5 and T6 are turned on in view of the logically low signal XQM. Also, the signal SQ1 at the node Q1 is pulled to a low logic level by the logically low signal XQM.

As a result, at time t3, since the transistor T5 is turned on and the transistor T3 is turned off, the output signal S[M] is pulled to the logically high VGH.

After the operation of the third phase, the output signal S[M] of the register stage ST_M, which lags behind the input signal S[M−1] by one line time, is provided to the next register stage ST_M+1 as an input. In summary, in the shift register 10 composed of the six transistors T1 through T6, an input signal S[M−1] is received at a first transistor T1 in response to a first control signal XCK during a first phase. During the first phase, the first, second and third transistors T1, T2 and T3 are kept at an on state, while the fourth, fifth and sixth transistors T4, T5 and T6 are kept at an off state. Next, the received input signal S[M−1] is shifted as an output S[M] by the third transistor T3 in response to a second control signal CK during a second phase. During the second phase, the transistors T2 and T3 are kept at an on state, while the transistors T1 and T4 to T6 are kept at an off state. Subsequently, a shift operation to move the input signal S[M−1] from a previous register stage ST_M−1 to the current register stage ST_M is done. The shift operation ends in response to a third control signal XQM during a third phase. During the third phase, the transistors T1 to T3 are kept at an off state, while the transistors T4 to T6 are kept at an on state.

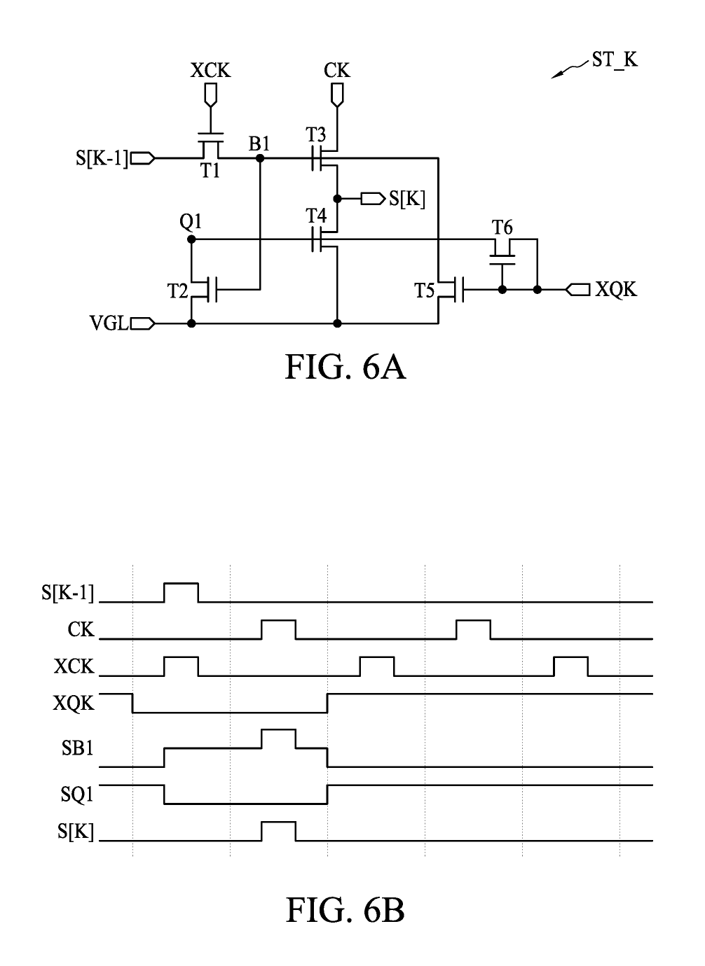

FIG. 6A is a circuit diagram of an exemplary register stage ST_K in the shift register 10 illustrated in FIG. 1, in accordance with another embodiment.

Referring to FIG. 6A, the register stage ST_K, K being a natural number from 1 to N, is similar to the register stage ST_M described and illustrated with reference to FIG. 2A except that, for example, the p-type transistors T1 through T6 are replaced by n-type transistors. Specifically, a gate of the transistor T1 receives the control signal XCK. A drain of the transistor T1 receives an input signal S[K−1] from a previous register stage ST_K−1, if K is greater than 1, or an initial input S[START], if K equals 1. Further, a gate of the transistor T2 is coupled at a node B1 to a source of the transistor T1. A source of the transistor T2 receives another supply voltage VGL, which may be ground level or minus five (−5) volts. In addition, a gate of the transistor T3 is coupled at the node B1 to the source of the transistor T1 and also to the gate of the transistor T2. A drain of the transistor T3 receives the control signal CK. A source of the transistor T3 provides an output S[K].

Moreover, a gate of the transistor T4 is coupled at a node Q1 to a drain of the transistor T2. A source of the transistor T4 receives the supply voltage VGL. A drain of the transistor T4 is coupled to the source of the transistor T3. Further, a gate of the transistor T5 receives the control signal XQK. A source of the transistor T5 receives the supply voltage VGL. A drain of the transistor T5 is coupled to the gate of the transistor T3 and also to the source of the transistor T1 and the gate of the transistor T2. In addition, a gate of the transistor T6 receives the control signal XQK. A drain of the transistor T6 also receives the control signal XQK. A source of the transistor T6 is coupled to the gate of the transistor T4 and the drain of the transistor T2.

In an embodiment, each of the transistors T1 through T6 includes an n-type thin film transistor (TFT) or an n-type metal-oxide-semiconductor (NMOS) transistor.

FIG. 6B is a timing diagram of signals for operation of the exemplary register stage ST_K illustrated in FIG. 6A, in accordance with some embodiments.

Referring to FIG. 6B, the control signals CK, XCK and XQK are similar to the control signals CK, XCK and XQM described and illustrated with reference to FIG. 3B, 4B or 5B except that, for example, the control signals CK, XCK and XQK in FIG. 6B are active high or asserted at a rising edge in view of the n-type transistors T1 through T6 in the register stage ST_K. As a result, the input signal S[K−1], the output signal S[K] and the node signals SB1 and SQ1 have an inverted phase with respect to the input signal S[M−1], the output signal S[M] and the node signals SB1 and SQ1 described and illustrated with reference to FIG. 3B, 4B or 5B.

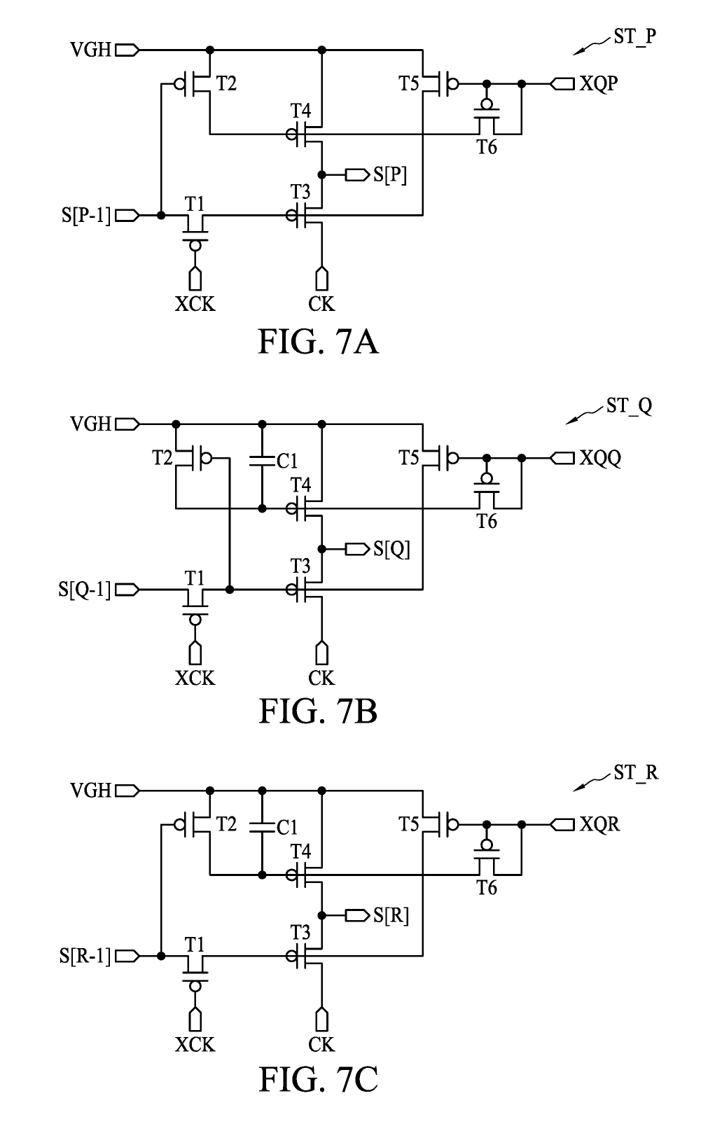

FIG. 7A is a circuit diagram of an exemplary register stage ST_P in the shift register 10 illustrated in FIG. 1, in accordance with yet another embodiment.

Referring to FIG. 7A, the register stage ST_P, P being a natural number from 1 to N, is similar to the register stage ST_M described and illustrated with reference to FIG. 2A except that, for example, an input signal S[P−1] is coupled at the source of the transistor T1, rather than at the drain of the transistor T1 or the node B1, to the gate of the transistor T2.

FIG. 7B is a circuit diagram of an exemplary register stage ST_Q in the shift register 10 illustrated in FIG. 1, in accordance with still another embodiment.

Referring to FIG. 7B, the register stage ST_Q, Q being a natural number from 1 to N, is similar to the register stage ST_M described and illustrated with reference to FIG. 2A except that, for example, a capacitor C1 is added between the source and the drain of the transistor T2. The capacitor C1 is configured to alleviate noise in the register stage ST_Q.

FIG. 7C is a circuit diagram of an exemplary register stage ST_R in the shift register 10 illustrated in FIG. 1, in accordance with yet still another embodiment.

Referring to FIG. 7C, the register stage ST_R, R being a natural number from 1 to N, is similar to the register stage ST_P described and illustrated with reference to FIG. 7A except that, for example, a capacitor C1 is added between the source and the drain of the transistor T2. The capacitor C1 helps alleviate noise in the register stage ST_R.

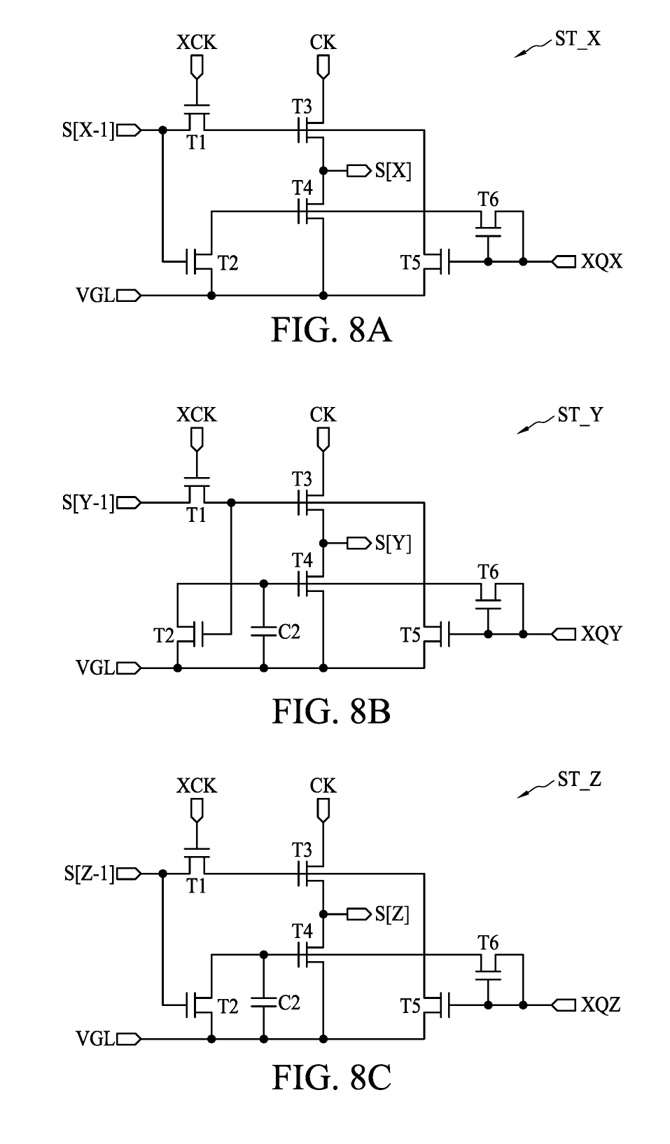

FIG. 8A is a circuit diagram of an exemplary register stage ST_X in the shift register 10 illustrated in FIG. 1, in accordance with yet another embodiment.

Referring to FIG. 8A, the register stage ST_X, X being a natural number from 1 to N, is similar to the register stage ST_K described and illustrated with reference to FIG. 6A except that, for example, an input signal S[X−1] is coupled at the drain of the transistor T1, rather than at the source of the transistor T1 or the node B1, to the gate of the transistor T2.

FIG. 8B is a circuit diagram of an exemplary register stage ST_Y in the shift register 10 illustrated in FIG. 1, in accordance with still another embodiment.

Referring to FIG. 8B, the register stage ST_Y, Y being a natural number from 1 to N, is similar to the register stage ST_K described and illustrated with reference to FIG. 6A except that, for example, a capacitor C2 is added between the source and the drain of the transistor T2. The capacitor C2 is configured to alleviate noise in the register stage ST_Y.

FIG. 8C is a circuit diagram of an exemplary register stage ST_Z in the shift register 10 illustrated in FIG. 1, in accordance with yet still another embodiment.

Referring to FIG. 8C, the register stage ST_Z, Z being a natural number from 1 to N, is similar to the register stage ST_X described and illustrated with reference to FIG. 8A except that, for example, a capacitor C2 is added between the source and the drain of the transistor T2. The capacitor C2 helps alleviate noise in the register stage ST_Z.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A shift register, comprising:
a number of register stages, each of the register stages comprising:
a first transistor, including a gate to receive a first control signal (XCK), and a source to receive an input signal in response to the first control signal;
a second transistor, including a source to receive a supply voltage; and
a third transistor, including a gate coupled to the drain of the first transistor,
a source to receive a second control signal, and a drain to provide the input signal as an output in response to the second control signal.

2. The shift register according to claim 1, wherein the each register stage further comprises:
a fourth transistor, including a source to receive the supply voltage, and a drain coupled to the drain of the third transistor;
a fifth transistor, including a gate to receive a third control signal, a source to receive the supply voltage, and a drain coupled to the gate of the third transistor; and
a sixth transistor, including a gate to receive the third control signal, a source to receive the third control signal, and a drain coupled to a gate of the fourth transistor and to a drain of the second transistor.

3. The shift register according to claim 2 being composed of the first through sixth transistors.

4. The shift register according to claim 2, wherein the drain of the first transistor is coupled to a gate of the second transistor, further comprising a capacitor coupled between the source and the drain of the second transistor.

5. The shift register according to claim 2, wherein the source of the first transistor is coupled to a gate of the second transistor, further comprising a capacitor coupled between the source and the drain of the second transistor.

6. The shift register according to claim 2, wherein each of the first through sixth transistors includes a p-type transistor, and the supply voltage has a logically high level.

7. The shift register according to claim 2, wherein each of the first through sixth transistors includes an n-type transistor, and the supply voltage has a logically low level.

8. The shift register according to claim 1, wherein the first transistor is configured to receive an initial signal as the input signal.

9. The shift register according to claim 1, wherein the first transistor is configured to receive an output from a previous register stage as the input signal.

10. The shift register according to claim 1, wherein the input signal has a period of one frame time, and a pulse width not greater than one line time.

11. The shift register according to claim 1, wherein the first control signal has a period of two line times, and a pulse width not greater than one line time.

12. The shift register according to claim 1, wherein the second control signal has a period of two line times, and a pulse width not greater than one line time.
